(19) United States
(12) Patent Application Publication
(10) Pub. No.: US 2004/0065910 A1
(43) Pub. Date: Apr. 8, 2004

(54) Image sensor having pixel isolation region

(76) Inventors: Hayashimoto Yoshiaki, Yokohama (JP); Young-Joo Seo, Buchun-si (KR)

Correspondence Address: CANTOR COLBURN LLP, 55 Griffin South Road, Bloomfield, CT, 06002, US

(21) Appl. No.: 10/300,035

(22) Filed: Nov. 19, 2002

(30) Foreign Application Priority Data
Oct. 4, 2002 (KR) 2002-60469

(51) Int. Cl. H01L 31/062; H01L 31/113

(52) U.S. Cl. 257/291

(57) ABSTRACT

Disclosed is an image sensor having a pixel isolation region. The image sensor includes a semiconductor substrate, a plurality of unit pixel regions for light-conversing an incident light upon a surface of the semiconductor substrate, and a pixel isolation region positioned between the adjacent unit pixel regions. The pixel isolation region includes an impurity region formed by implanting an ion into the substrate for shielding a leakage current generated between the adjacent unit pixel regions and a light shielding film formed on a surface of the impurity region for preventing the incident light from diffusing into the adjacent unit pixel region.

### BACKGROUND OF THE INVENTION

1. Field of the Invention

The present invention relates to an image sensor having a unit pixel isolation region, and more particularly, to an image sensor including an impurity region for shielding leakage current among adjacent unit pixels, and a light shielding film for preventing diffusion of an incident light.

2. Description of the Related Art

An image sensor is a device for converting one-dimensional or two-dimensional optical information into an electric signal, which is generally classified into a pickup tube and a solid-state imaging device. The camera tube is widely used in the field of measuring machine, control system, sensor or the like on the basis of a television, which utilizes an image processing technique, and its application technology has been developed.

The image sensor commercially available generally includes a charge coupled device (CCD) image sensor and a complementary metal oxide semiconductor (CMOS) image sensor.

The CMOS image sensor is a device for converting optical image into the electric signal by use of CMOS manufacturing technology, and employs a switching mode for detecting an output from MOS transistors corresponding to each pixel in turn. Compared with the conventional CCD image sensor that is widely used as the image sensor, the CMOS sensor is easily operated, and includes various scanning modes. In addition, since a signal processing circuit may be manufactured in a single chip, it may be minimized. Furthermore, the compatible CMOS technology is acceptable, its manufacturing cost may be reduced, and power consumption may also be remarkably reduced. Because of these advantages, the CMOS image sensor has been more widely used than the CCD image sensor.

FIG. 1 shows the structure of the CMOS image sensor, in which a reference numeral 10 indicates a pixel isolation region, 12 indicates a photo diode, and 14 indicates a gate electrode.

Referring to FIG. 1, the CMOS image sensor includes a plurality of unit pixel region containing the photo diode 12 and the gate electrode 14 for converting the incident light into the electric signal, which is arrayed adjacent to other region. The resolution of image converted into the electric signal is determined depending upon the number of the unit pixel regions. Therefore, a plurality of unit pixel regions are arrayed adjacent to one another in order to improve the resolution, and then the pixel isolation region 10 is disposed between the adjacent unit pixel regions in order to electrically isolate between them.

Heretofore, the pixel isolation region 10 has been formed through a local oxidation of silicon (LOCOS) or shallow trench isolation (STI) process. In particular, the LOCOS process, that is, an oxide film is exposed to grow through a thermal oxidation process, is mainly used because a manufacturing method is relatively simple.

FIGS. 2a to 2d show the conventional LOCOS process for forming the pixel isolation region.

First, as shown in FIG. 2a , a silicon oxide film (e.g., SiO₂) and a silicon nitride film (e.g., Si₃N₄) are formed on a silicon substrate. And then, as shown in FIG. 2b , the silicon nitride film, disposed on a portion on which the pixel isolation region is formed, is removed from the substrate using a plasma apparatus.

After the silicon nitride film is removed and the silicon film is exposed, as shown in FIG. 2c , the exposed silicon oxide film is expanded by a high-temperature thermal annealing process.

If the process of expanding the silicon oxide film is completed, as shown in FIG. 2d , the remaining silicon nitride film is removed through a dry etching process using the plasma apparatus. The pixel isolation region is formed between the unit pixel regions arrayed adjacent to each other through the above processes.

Meanwhile in the LOCOS process, the plasma etching process is repeatedly executed to remove the silicon nitride film. Hence, A high temperature of the plasma causes the silicon substrate to be damaged in the etching process, thereby producing a white scratch in the image sensor.

To solve the above-mentioned problem of the LOCOS process, several inventions have been proposed. For example, Korean Patent Publication No. 2000-64430 discloses a CMOS image sensor with an isolation region that is ion-implanted impurity layer between the unit pixel regions.

Also, Korean Patent Publication No. 2000-51300 discloses a method of forming an impurity layer under an isolation film for isolation.

However, though the pixel isolation region formed after the above-mentioned techniques successfully provides the electrical isolation between the adjacent unit pixel regions, it does not prevent the incident light from diffusing into the adjacent unit pixel regions.

### SUMMARY OF THE INVENTION

The present invention is designed to solve the problems of the prior art, and therefore an object of the present invention is to provide an image sensor with a pixel isolation region capable of reducing a damage of a silicon substrate due to a plasma etching and preventing an incident light from diffusing into adjacent pixel regions.

This object, other incidental ends and advantages of the invention will hereinafter appear in the progress of the disclosure and as pointed out in the appended claims.

In order to accomplish the above object, the present invention provides an image sensor comprising: a semiconductor substrate; a plurality of unit pixel regions for conversing an incident light upon a surface of the semiconductor substrate into electric signal; and a pixel isolation region positioned between the adjacent unit pixel regions, wherein the pixel isolation region includes: an impurity region formed by implanting an ion into the substrate for shielding a leakage current generated between the adjacent unit pixel regions; and a light shielding film formed on a surface of the impurity region for preventing the incident light from diffusing into the adjacent unit pixel region.

It is preferable that the impurity region is formed by doping a P-type or N-type impurity into the semiconductor substrate.

Also, It is preferable that the light shielding film is made of an opaque insulating material, and more preferably, silicon oxide or opaque polymer resin.

Meanwhile, It is preferable that the unit pixel region is formed using a process of manufacturing a CMOS semiconductor or a CCD semiconductor.

Also, It is preferable that the unit pixel region includes: an oxide film formed on the semiconductor substrate; a gate electrode positioned on the oxide film; a photodiode N-type region formed within the semiconductor substrate and having an interface on an upper portion thereof, the photodiode N-type region being spaced apart from the gate electrode by a predetermined distance and being disposed on one side of the gate electrode; and an N-type region acting as a floating diffusion region, formed within the semiconductor substrate and having an interface on an upper portion thereof, the N-type region being spaced apart from the gate electrode by a predetermined distance and being disposed on the other side of the gate electrode.

### BRIEF DESCRIPTION OF THE DRAWINGS

These and other features, aspects, and advantages of the present invention will become better understood with regard to the following description, appended claims, and accompanying drawings, in which like components are referred to by like reference numerals. In the drawings:

FIG. 1 is a cross-sectional view showing a structure of a conventional CMOS image sensor;

FIGS. 2a to 2d are cross-sectional views showing a conventional LOCOS process of isolating a pixel;

FIG. 3 is a cross-sectional view showing an image sensor with a pixel isolated in accordance with a preferred embodiment of the present invention;

FIGS. 4a to 4e are cross-sectional views showing a pixel isolating process in accordance with a preferred embodiment of the present invention; and

FIGS. 5a to 5c are cross-sectional views showing a structure of a unit pixel region in accordance with a preferred embodiment of the present invention.

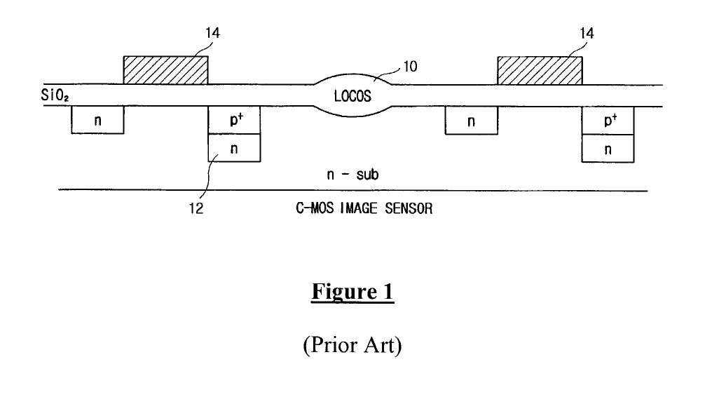

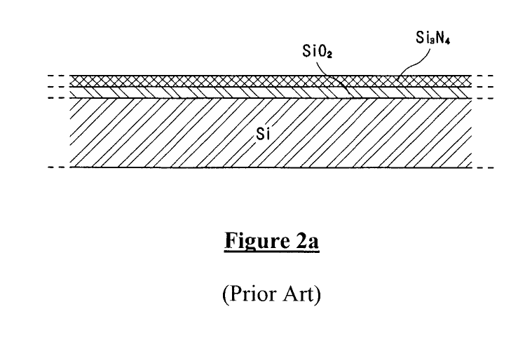

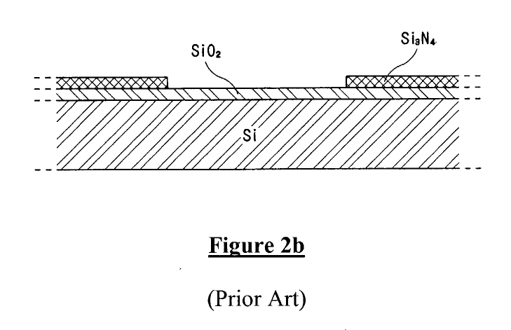

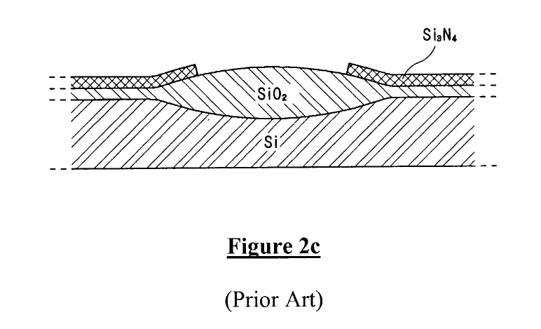

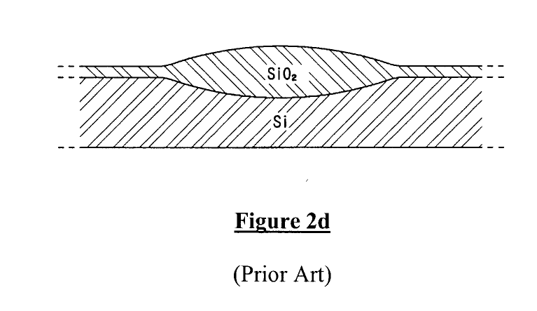

### DETAILED DESCRIPTION OF THE PREFERRED EMBODIMENT

Hereinafter, preferred embodiments of the present invention will be described in detail with reference to the accompanying drawings.

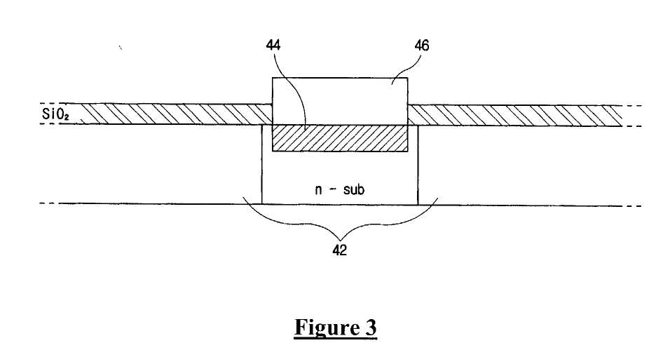

FIG. 3 shows an image sensor with a pixel isolation region formed by a preferred embodiment of the present invention, in which a reference numeral 42 indicates a unit pixel region, 44 indicates an impurity region, and 46 indicates a light shielding film.

The impurity region 44 is formed by ion-implanting a P-type or N-type impurity depending upon a kind of a semiconductor substrate for shielding a leakage current between the unit pixel regions 42. The light shielding film 46 is formed to interface with the impurity region, and serves as a role of preventing the incident light from diffusing into the unit pixel regions 42. Heretofore, though the electrical isolation between the adjacent unit pixel regions 42 is achieved by implanting the impurity into the semiconductor substrate, it cannot shield the incident light diffused into the unit pixel region 42. According to the present invention, however, it is possible to shield the diffused light into the adjacent unit pixel region 42 by forming the light shielding film on an upper portion of the impurity region 44.

The pixel isolation region having the impurity region 44 and the light shielding film 46 may be applied to any kinds of image sensors accumulating the light to generate the electric signal, as well as commonly used image sensors such as CCD, CMOS and so forth. In particular, it may be applied to an NMOS image sensor which is filed by the same inventors.

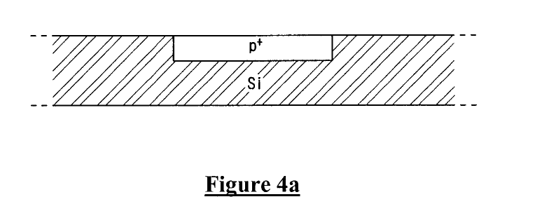

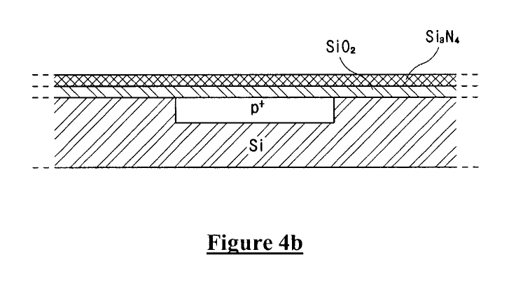

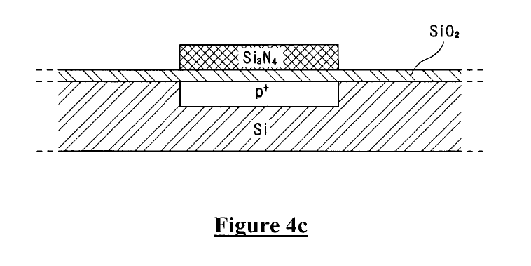

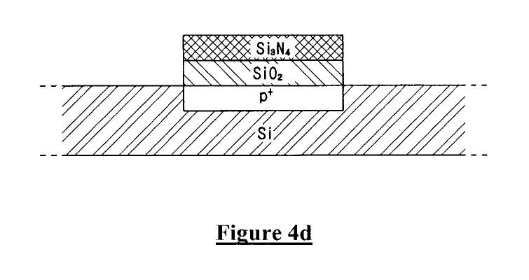

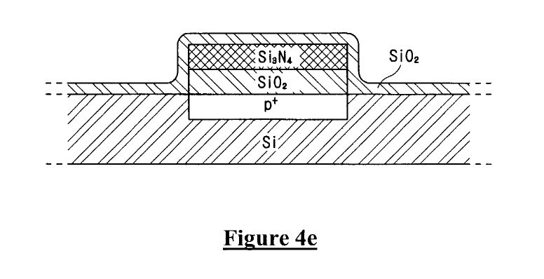

FIGS. 4a to 4e show a process of forming the pixel isolation region having the impurity region and the light shielding film according to the preferred embodiment of the present invention. The above process will help to minimize the damage of the silicon substrate due to the plasma etching.

First, as shown in FIG. 4a , the impurity region for shielding the leakage current between the unit pixel regions is formed on the silicon substrate through ion-implantation. The impurity layer may contain a P-type impurity or an N-type impurity depending upon a kind of the silicon substrate.

If the ion implantation of the impurity layer is completed, as shown in FIG. 4b, a silicon oxide film (e.g., SiO₂) and a silicon nitride film (e.g., Si₃N₄) are formed on the silicon substrate. At that time, preferably, the silicon oxide film is formed to be thicker than the silicon oxide film formed by the conventional LOCOS process.

After the silicon oxide film and the silicon nitride film are formed, as shown in FIG. 4c, the silicon nitride film is locally removed from the substrate through a dry etching process using a plasma apparatus, except for a portion on which the pixel isolation region is formed.

Although the process includes the hot plasma etching like the conventional LOCOS process, the damage to the silicon substrate may be avoided through damping action resulted from the thick silicon oxide film formed thereon.

If etching the silicon nitride film is completed, as shown in FIG. 4d, the silicon oxide film is removed using the locally remained silicon nitride film as a mask, which may be executed by a wet etching process using chemicals. When the silicon substrate except for the pixel isolation region is formed thereon is exposed, the process of forming the pixel isolation region according to the present invention is completed.

After that, as shown in FIG. 4e , it is desirable that an oxide film is formed on the silicon substrate for protecting the exposed substrate.

The pixel isolation region formed by this process includes the P-type or N-type impurity region formed by ion-implanting into the silicon substrate, and the light shielding film formed on the silicon substrate.

In this embodiment, although the light shielding film is made of silicon oxide and silicon nitride, it may be made of polymer resin or opaque insulating material by varying the above process.

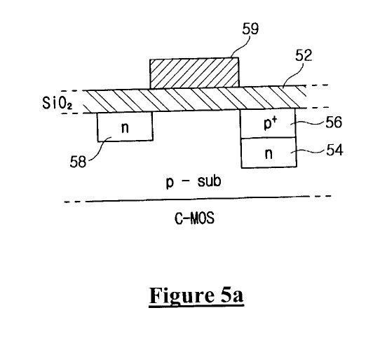

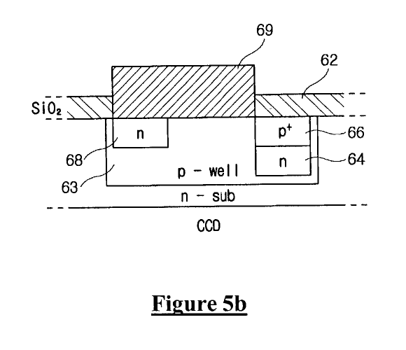

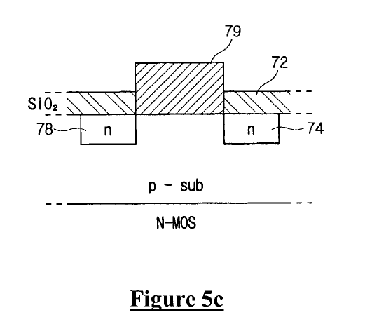

FIGS. 5a and 5c illustrates various image sensors applied with the unit pixel region according to another preferred embodiment of the present invention.

FIG. 5a shows a CMOS type of image sensor applied with the unit pixel region according to the present invention.

As shown in FIG. 5a , the CMOS type of unit pixel region includes an oxide film 52 formed on a semiconductor substrate, a photodiode N-type region 54 formed in the semiconductor substrate in a certain depth, a photodiode surface P-type region 56, positioned on an upper portion of the photodiode N-type region and having an interface with the oxide film 52, a floating diffusion region 58, positioned in the semiconductor substrate and spaced apart from the photodiode region 54 and 56 and having an interface with the oxide film 52, and a gate electrode 59 positioned on the substrate between the floating diffusion region 58 and the photodiode regions 54 and 56.

In the unit pixel region of the CMOS image sensor, a photoelectric conversion of an incident light into an electric signal is performed in the photodiode N-type region 54 to generate a signal charge, which is introduced into the floating diffusion region 58 through the photodiode surface P-type region 56. The signal charge is amplified in the floating diffusion region 58, which is converted into a voltage signal so that the CMOS image sensor outputs the voltage signal.

Generally, the gate electrode 59 is aligned with the floating diffusion region 58 and the photodiode regions 54 and 56, which is made of doped polycrystalline silicon.

FIG. 5b shows a CCD type of image sensor applied with the unit pixel region according to the present invention.

As shown in FIG. 5b , the CCD type of unit pixel region includes an oxide film 62 formed on a semiconductor substrate, a photodiode N-type region 64 formed in the semiconductor substrate in a certain depth, a photodiode surface P-type region 66, positioned on an upper portion of the photodiode N-type region 64 and having an interface with the oxide film 62, a floating diffusion region 68 positioned in the semiconductor substrate and spaced apart from the photodiode region 64 and 66 and having an interface with the oxide film 62, a gate electrode 69 positioned on an upper portion of the floating diffusion region 68, and a P-type well region 63 including the photodiode N-type region 64, the photodiode surface P-type region 66 and the floating diffusion region 68.

In the unit pixel region of the CCD image sensor, a photoelectric conversion of an incident light into an electric signal is performed in the photodiode N-type region 64 to generate a signal charge, which is introduced into the floating diffusion region 68 through the photodiode surface P-type region 66 and the P-type well region 63. The signal charge is amplified in the floating diffusion region 68, which is converted into a voltage signal so that the CMOS image sensor outputs the voltage signal. Generally, the gate electrode 69 is overlapped with the floating diffusion region 68, which is made of doped polycrystalline silicon.

FIG. 5c shows an NMOS type of image sensor applied with the unit pixel region according to the present invention.

As shown in FIG. 5c , the NMOS type of unit pixel region includes an oxide film 72 formed on a semiconductor substrate, a gate electrode 79 formed on an upper portion of the oxide film, a photodiode N-type region 74, formed within the semiconductor substrate and having an interface with the oxide film 72, in which the photodiode N-type region is spaced apart from the gate electrode 79 by a predetermined distance and disposed on one side of the gate electrode, and a N-type region acting as a floating diffusion region 78, formed within the semiconductor substrate and having an interface with the oxide film 72, in which the floating diffusion region is spaced apart from the gate electrode 79 by a predetermined distance and disposed on the other side of the gate electrode.

The operation of the NMOS type of image sensor is substantially similar to that disclosed in the application filed by the inventor, the description of which will be omitted.

The pixel isolation region of the present invention may be applied to any kind of image sensors accumulating the light to output the electric signal, as well as commonly used image sensors such as CCD, CMOS and so forth.

With the structure of the unit pixel region as described above, it may prevent the damage to the silicon substrate through the damping action of the thick silicon oxide film formed thereon when implementing the plasma etching. In addition, as an additional light shielding film for effectively shielding the diffused light is included, the performance of the image sensor may be improved.

The image sensor according to the present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

What is claimed is:

1. An image sensor comprising:
a semiconductor substrate;
a plurality of unit pixel regions for conversing an incident light upon a surface of the semiconductor substrate into electric signal; and
a pixel isolation region positioned between the adjacent unit pixel regions,
wherein the pixel isolation region includes:
an impurity region formed by implanting an ion into the substrate for shielding a leakage current generated between the adjacent unit pixel regions; and
a light shielding film formed on a surface of the impurity region for preventing the incident light from diffusing into the adjacent unit pixel region.

2. The image sensor according to claim 1,
wherein the impurity region is formed by doping a P-type or N-type impurity into the semiconductor substrate.

3. The image sensor according to claim 1,
wherein the light shielding film is made of an opaque insulating material.

4. The image sensor according to claim 3,
wherein the opaque insulating material is silicon oxide.

5. The image sensor according to claim 3,
wherein the opaque insulating material is opaque polymer resin.

6. The image sensor according to claim 1,
wherein the unit pixel region is formed using a process of manufacturing a CMOS semiconductor.

7. The image sensor according to claim 1,
wherein the unit pixel region is formed using a process of manufacturing a CCD semiconductor.

8. The image sensor according to claim 1,
wherein the unit pixel region includes:
an oxide film formed on the semiconductor substrate;
a gate electrode positioned on the oxide film;
a photodiode N-type region formed within the semiconductor substrate and having an interface with the oxide film, the photodiode N-type region being spaced apart from the gate electrode by a predetermined distance and being disposed on one side of the gate electrode; and
an N-type region acting as a floating diffusion region, formed within the semiconductor substrate and having an interface with the oxide film, the N-type region being spaced apart from the gate electrode by a predetermined distance and being disposed on the other side of the gate electrode.
